(19) United States
(12) Patent Application Publication
(10) Pub. No.: US 2026/0202444 A1
(43) Pub. Date: Jul. 16, 2026

(54) MAGNETIC COUPLING DEGREE DETECTION DEVICE AND ELECTRONIC CONTROL UNIT

(71) Applicant: DENSO CORPORATION, Kariya-city (JP)

(72) Inventor: Kei SANADA, Kariya-city (JP)

(21) Appl. No.: 19/398,279

(22) Filed: Nov. 24, 2025

(30) Foreign Application Priority Data
Jan. 10, 2025 (JP) 2025-004257

(51) Int. Cl. G01R 15/18; G01R 19/00; G01R 33/12

(52) U.S. Cl. CPC G01R 15/183; G01R 19/0092; G01R 33/1215

(57) ABSTRACT

A magnetic coupling degree detection device includes a current detector and a coupling degree detector. The current detector detects a current flowing through a driver of a multiphase power supply, in which the inductors of a plurality of phases are configured by a coupled inductor and which supplies power to a load. The coupling degree detector detects the degree of magnetic coupling of the coupled inductor based on the current value detected by the current detector. The coupling degree detector determines that the degree of magnetic coupling is low when the differential value of the current value is within a predetermined range, compared to when the differential value of the current value exceeds the upper limit of the predetermined range.

### CROSS REFERENCE TO RELATED APPLICATIONS

This application is based on Japanese Patent Application No. 2025-004257 filed on Jan. 10, 2025, the description of which is incorporated herein by reference.

### TECHNICAL FIELD

The disclosure in this specification relates to a magnetic coupling degree detection device and an electronic control unit including the magnetic coupling degree detection device.

### BACKGROUND

A magnetic detection device is known.

### SUMMARY

One object of the present disclosure is to provide a technique capable of detecting a low degree of coupling of a coupled inductor.

### MEANS FOR SOLVING THE PROBLEM

A magnetic coupling degree detection device according to one aspect of the disclosure includes:
a current detector configured to detect a current flowing in a driver of a multiphase power supply in which inductors of a plurality of phases are configured by a coupled inductor and which supplies power to a load; and
a coupling degree detector configured to detect a magnetic coupling degree of the coupled inductor based on a current value detected by the current detector.

The coupling degree detector determines that the degree of magnetic coupling is low when the differential value of the current value is within a predetermined range, compared to when the differential value of the current value exceeds the upper limit of the predetermined range.

An electronic control unit according to other aspect of the disclosure includes:
a multiphase power supply having a plurality of phases each including a driver and an inductor, the inductor of each phase being configured by a coupled inductor;
a control unit configured to control an on/off of the driver;
a processor configured to receive power from the multiphase power supply and operate; and
a magnetic coupling degree detection device including a current detector configured to detect a current flowing in the driver, and a coupling degree detector configured to detect a magnetic coupling degree of the coupled inductor based on a current value detected by the current detector.

The coupling degree detector determines that the degree of magnetic coupling is low when the differential value of the current value is within a predetermined range, compared to when the differential value of the current value exceeds the upper limit of the predetermined range.

### BRIEF DESCRIPTION OF DRAWINGS

FIG. 1 is a diagram showing a magnetic coupling degree detection device and an electronic control unit according to a first embodiment;

FIG. 2 is a circuit diagram showing a multiphase power supply;

FIG. 3 is a perspective view showing a coupled inductor;

FIG. 4 is a plan view showing a coupled inductor;

FIG. 5 is a plan view of the coupled inductor as viewed from the opposite side to the plan view of FIG. 4;

FIG. 6 is a plan view showing a core;

FIG. 7 is a perspective view showing a coil;

FIG. 8 is a diagram showing a reference example of a coupled inductor with a large gap;

FIG. 9 is a diagram showing a reference example of a coupled inductor with different gaps due to tilted assembly;

FIG. 10 is a diagram showing Ip and Vout waveforms when a coupled inductor with a low degree of magnetic coupling is used;

FIG. 11 is a block diagram showing a coupling degree detection unit;

FIG. 12 is a flowchart showing a process executed by a coupling degree detection unit;

FIG. 13 is a diagram showing a relationship between a strength of magnetic coupling and a current gradient;

FIG. 14 is a timing chart showing various signal waveforms when the assembly is properly performed;

FIG. 15 is a timing chart showing various signal waveforms when the assembly is tilted;

FIG. 16 is a flowchart showing a process executed by a coupling degree detection unit in the magnetic coupling degree detection device and the electronic control unit according to a second embodiment;

FIG. 17 is a diagram showing a magnetic coupling degree detection device and an electronic control unit according to a third embodiment;

FIG. 18 is a diagram showing a modified example;

FIG. 19 is a diagram showing a modified example; and

FIG. 20 is a flowchart showing a process executed by a processor in an electronic control unit according to a fourth embodiment.

### DETAILED DESCRIPTION

A magnetic detection device is known. The disclosure of the prior art document (JP 2016-30151 A) is incorporated herein by reference as a explanation of the technical elements in this disclosure.

According to the document, magnetic changes can be detected for an independent inductor. However, in a configuration in which a plurality of inductors are magnetically coupled to one another, such as coupled inductors provided in a multiphase power supply, it is not possible to detect a degree of magnetic coupling between the inductors. In the above respects and in other respects not mentioned above, further improvements are required in magnetic coupling degree detection device and electronic control unit equipped with magnetic coupling degree detection device.

One object of the present disclosure is to provide a technique capable of detecting a low degree of coupling of a coupled inductor.

A magnetic coupling degree detection device according to one aspect of the disclosure includes:
a current detector configured to detect a current flowing in a driver of a multiphase power supply in which inductors of a plurality of phases are configured by a coupled inductor and which supplies power to a load; and
a coupling degree detector configured to detect a magnetic coupling degree of the coupled inductor based on a current value detected by the current detector.

The coupling degree detector determines that the degree of magnetic coupling is low when the differential value of the current value is within a predetermined range, compared to when the differential value of the current value exceeds the upper limit of the predetermined range.

According to the disclosed magnetic coupling degree detection device, the magnetic coupling degree between inductors in a coupled inductor is detected based on the current flowing through the driver. The gradient of the current, that is, the differential value, becomes larger as the magnetic coupling increases, and becomes smaller as the magnetic coupling decreases. Furthermore, in the period when the driver of any phase is off, the current decreases and the differential value becomes negative. The coupling degree detector determines that the degree of magnetic coupling is low, that is, the degree of magnetic coupling is low, when the differential value of the current value is within the predetermined range. Therefore, it is possible to detect a low degree of coupling of the coupled inductor. For example, it is possible to detect low coupling degree due to manufacturing variations, deterioration over time, etc.

An electronic control unit according to other aspect of the disclosure includes:
a multiphase power supply having a plurality of phases each including a driver and an inductor, the inductor of each phase being configured by a coupled inductor;
a control unit configured to control an on/off of the driver;
a processor configured to receive power from the multiphase power supply and operate; and
a magnetic coupling degree detection device including a current detector configured to detect a current flowing in the driver, and a coupling degree detector configured to detect a magnetic coupling degree of the coupled inductor based on a current value detected by the current detector.

The coupling degree detector determines that the degree of magnetic coupling is low when the differential value of the current value is within a predetermined range, compared to when the differential value of the current value exceeds the upper limit of the predetermined range.

The disclosed electronic control unit includes the above-described magnetic coupling degree detection device. The magnetic coupling degree detection device detects the degree of magnetic coupling degree between inductors in a coupled inductor based on the current flowing through the driver. The magnetic coupling degree detection device determines that the degree of magnetic coupling is low, that is, the degree of magnetic coupling is low, when the differential value of the current value is within the predetermined range. Therefore, it is possible to detect a low degree of coupling of the coupled inductor. For example, it is possible to detect low coupling degree due to manufacturing variations, deterioration over time, etc.

The multiple embodiments disclosed in this description employ different technical means to achieve their respective objectives. The objects, features, and advantages disclosed in this description will become apparent by referring to following detailed descriptions and accompanying drawings.

Hereinafter, a plurality of embodiments will be described with reference to the drawings. The same reference numerals are assigned to the corresponding elements in each embodiment, and thus, duplicate descriptions may be omitted. When only a part of the configuration is described in the respective embodiments, the configuration of the other embodiments described before may be applied to other parts of the configuration. Further, not only the combinations of the configurations explicitly shown in the description of the respective embodiments, but also the configurations of the plurality of embodiments can be partially combined even when they are not explicitly shown as long as there is no difficulty in the combination in particular.

### First Embodiment

First, an electronic control unit equipped with a magnetic coupling degree detection device according to the present embodiment will be described.

### Electronic control unit

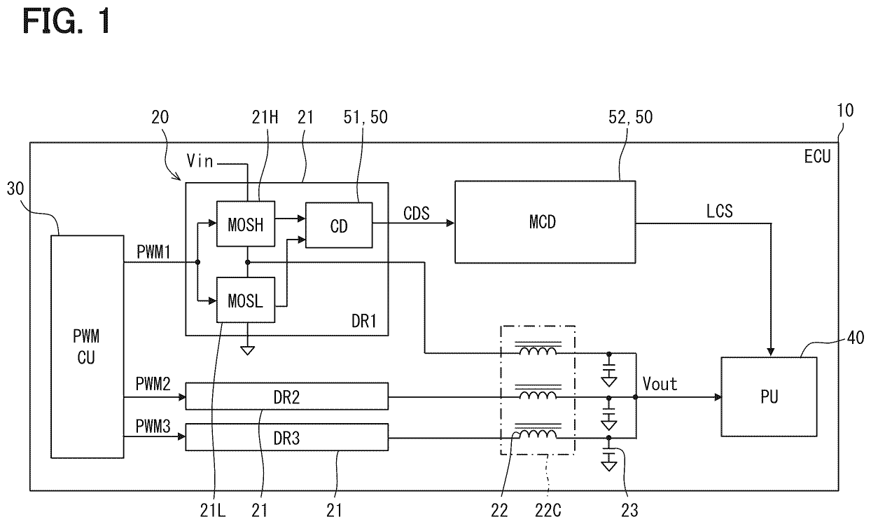

FIG. 1 shows an example of an electronic control unit according to the present embodiment. The electronic control unit 10 can be applied to, for example, a mobile object. Mobile objects include vehicles such as engine-driven vehicles, hybrid vehicles, and motor-driven vehicles, flying objects such as drones and eVTOLs, ships, construction machinery, and agricultural machinery. The eVTOL is an abbreviation for electric Vertical Take-Off and Landing aircraft. For example, when applied to a vehicle, the electronic control unit 10 controls devices mounted on the vehicle.

The illustrated electronic control unit 10 is an ECU mounted on the vehicle. ECU is an abbreviation of Electronic Control Unit. The electronic control unit 10 may be, for example, an autonomous driving ECU or an ADAS ECU that performs control to assist drivers with driving operations. ADAS is an abbreviation for Advanced Driving Assistant System. For example, levels 3 to 5 as defined by the Society of Automotive Engineers (SAE International) correspond to automatic driving levels, while levels 1 to 2 correspond to driving assistance levels. The electronic control unit 10 may be an infotainment ECU or a cockpit ECU. The cockpit ECU is an ECU that controls devices such as a meter device, a navigation device, and an air conditioning device. The electronic control unit 10 may be, for example, an integrated ECU that integrates a plurality of control functions.

The electronic control unit 10 includes a multiphase power supply 20, a control unit 30, a processor 40, and a magnetic coupling degree detection device 50. The electronic control unit 10 may include a processor 40 as well as a load separate from the processor 40.

### Multiphase Power Supply

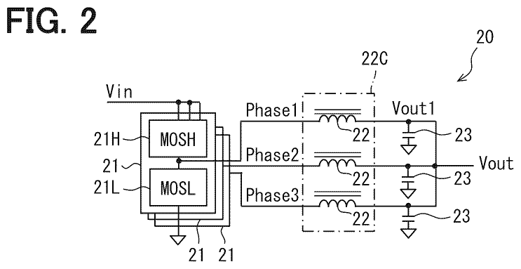

FIG. 2 is a circuit diagram showing a multiphase power supply. For convenience, some of the drivers are shown in a simplified form in FIG. 2. The multiphase power supply 20 is a power supply circuit. The multiphase power supply 20 steps down the input voltage to a predetermined voltage that can be supplied to a load such as the processor 40 and outputs the voltage. The multiphase power supply 20 is a step-down DC-DC converter. The multiphase power supply 20 steps down the input voltage Vin to a predetermined voltage (for example, around 1 V) and outputs it to the processor 40 as an output voltage Vout.

The electronic control unit 10 may also include a primary power supply circuit (not shown) that, together with the multiphase power supply 20, constitutes a power supply circuit. The primary power supply circuit is configured to be able to step down an input voltage to a predetermined voltage and output the voltage. The primary power supply circuit is a step-down DC-DC converter. The primary power supply circuit generates a constant voltage (for example, 5 V) lower than the power supply voltage (+B) based on power supplied from, for example, a battery mounted on the vehicle. In a configuration including a primary power supply circuit, the multiphase power supply 20 is a secondary power supply circuit that receives the voltage generated by the primary power supply circuit as an input voltage Vin.

As shown in FIGS. 1 and 2, the multiphase power supply 20 includes a plurality of drivers (DRs) 21, a coupled inductor 22C having a plurality of inductors 22, and a capacitor 23. The multiphase power supply 20 has a plurality of phases, each including a driver 21 and an inductor 22. A phase may be referred to as a stage, a channel, etc. The number of phases is not particularly limited. The exemplary multiphase power supply 20 has three phases. In FIG. 2, the three phases are shown as Phase 1, Phase 2, and Phase 3. In FIG. 1, the number added to the end of DR indicates which phase it constitutes. For example, DR1 is the driver 21 that constitutes Phase 1.

The exemplary driver 21 includes MOSFETs 21H and 21L. MOSFET is an abbreviation for Metal Oxide Semiconductor Field Effect Transistor. Instead of the MOSFETs 21H and 21L, other switching elements such as IGBTs may be used. The IGBT is an abbreviation of an insulated gate bipolar transistor. The MOSFETs 21H and 21L are connected in series between a power supply line to which an input voltage Vin is input and a ground (GND) line, with the MOSFET 21H on a high side and the MOSFET 21L on a low side. In FIGS. 1 and 2, the MOSFET 21H on the high side is indicated as MOSH, and the MOSFET 21L on the low side is indicated as MOSL. The exemplary driver 21 has a drive circuit (not shown) that turns on and off the MOSFETs 21H and 21L based on a PWM signal (described later).

One end of the inductor 22 is connected to the connection point (node) of the MOSFETs 21H and 21L. The other end of the inductor 22 is connected to an output line. The inductor 22 is provided individually for the driver 21. The driver 21 and the inductor 22 of each phase are connected in parallel with each other. The parallel connection allows the output current, and therefore the load current, from the multiphase power supply 20 to be increased.

The capacitor 23 is connected to the output line. The positive terminal of the capacitor 23 is connected to the output line. The negative terminal of the capacitor 23 is connected to the ground. The capacitor 23 may be provided individually for each phase, or may be provided in common for a plurality of phases. In the exemplary multiphase power supply 20, a capacitor 23 is provided for each phase.

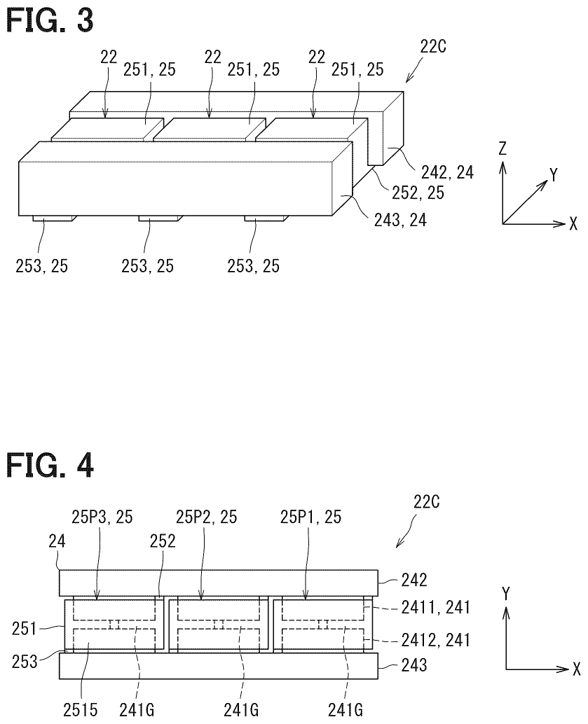

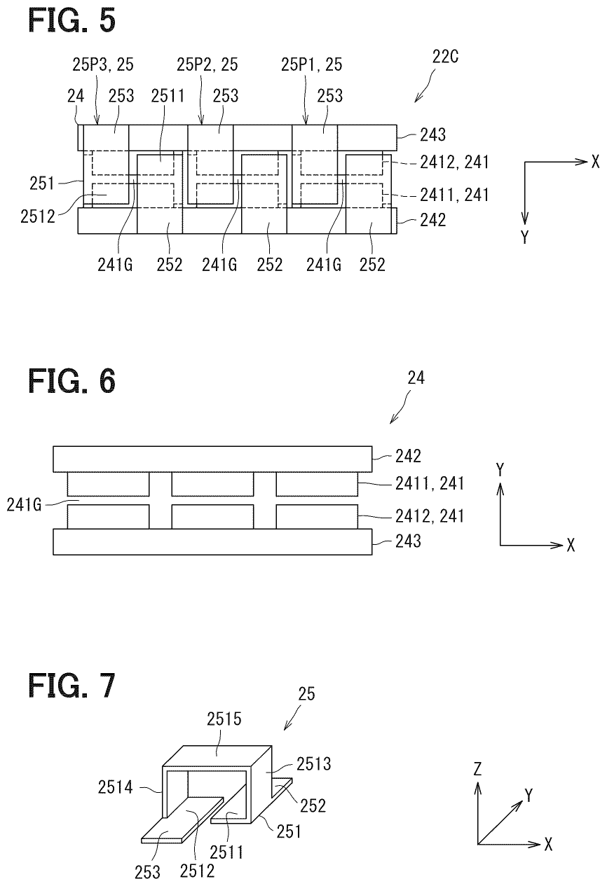

FIG. 3 is a perspective view showing an example of a coupled inductor. FIG. 4 is a plan view of the coupled inductor shown in FIG. 3 as seen from a top side. FIG. 5 is a plan view of the coupled inductor shown in FIG. 3 as viewed from a bottom side. FIG. 6 is a plan view showing a core. FIG. 7 is a perspective view showing a coil. A single coupled inductor 22C provides multiple inductors 22 that make up the multiphase power supply 20.

In the following description, the direction in which a plurality of coils are arranged is referred to as the X direction. A direction perpendicular to the X direction and in which the two ends are aligned is referred to as the Y direction. A direction perpendicular to both the X direction and the Y direction is referred to as the Z direction. Unless otherwise specified, a shape viewed in a plane from the Z-direction, that is, a shape along an XY plane defined by the X-direction and Y-direction is referred to as a planar shape. The plan view from the Z direction may be simply referred to as a plan view. The X direction corresponds to the predetermined direction.

As shown in FIGS. 3 to 5, the coupled inductor 22C includes a core 24 and a plurality of coils 25. One coil 25 constitutes one inductor 22. The plurality of coils 25 are arranged on one core 24, that is, a common core 24, and are magnetically coupled to one another. By using the coupled inductor 22C, magnetic fluxes between the phases can be cancelled out, and the effective inductance can be reduced.

The core 24 is formed using a magnetic material such as ferrite. The core 24 functions as a magnetic circuit. The core 24 has a plurality of central cores 241 and first and second end cores 242 and 243. The central core 241 corresponds to the core. The first end core 242 corresponds to the first end, and the end core 243 corresponds to the second end. The core 24 has a coil 25 inserted therethrough. The core 24 has the same number of central cores 241 as the number of phases. The central core 241 is provided individually for each coil 25. The coil 25 is wound around the central core 241. The central core 241 extends in the Y direction. The multiple central cores 241 are arranged in the X direction at predetermined intervals. The exemplary core 24 has three central cores 241. Each of the central cores 241 has a substantially rectangular parallelepiped shape. The three central cores 241 have the same shape.

The first and second end cores 242 and 243 are disposed opposite each other in the Y direction. The first and second end cores 242 and 243 sandwich the central core 241 therebetween. The first and second end cores 242 and 243 extend in the X direction, which is the direction in which the multiple central cores 241 are arranged. One ends of the plurality of central cores 241 are connected to the first end core 242, and the other ends of the plurality of central cores 241 are connected to the second end core 243. The first and second end cores 242 and 243 magnetically connect the plurality of central cores 241 together. The exemplary first and second end cores 242 and 243 have the same shape. The first and second end cores 242 and 243 are generally rectangular parallelepipeds with the X direction as the longitudinal direction.

Each of the central cores 241 is divided into a plurality of sections in the Y direction, which is the direction in which the first and second end cores 242 and 243 face each other. The exemplary central core 241 is divided at the center in the Y direction. The central core 241 includes a first central core 2411 and a second central core 2412. In the Y direction, the lengths of the first central core 2411 and the second central core 2412 are approximately equal. The first central core 2411 is connected to the first end core 242. The first central core 2411 extends from the surface of the first end core 242 facing the second end core 243 toward the second end core 243. The second central core 2412 is connected to the second end core 243. The second central core 2412 extends from the surface of the second end core 243 facing the end core 242 toward the first end core 242.

The core 24 has a gap 241G between the opposing surfaces of the first central core 2411 and the second central core 2412, where no magnetic member is disposed. The gap 241G is a gap (space) between the first and second central cores 2411 and 2412. An adhesive, for example, is placed in the gap 241G to fix the opposing first and second central cores 2411 and 2412 to each other. It should be noted that a division position is not limited to the center. For example, the division position may be set at a position shifted from the center.

The coil 25 is made of a metal material with good conductivity, such as copper. The coil 25 is formed by processing a metal plate material, rather than a metal wire material. The metal plate material is sometimes referred to as a metal frame. The plurality of coils 25 are made of the same material and have the same shape. The plurality of coils 25 have approximately the same inductance. The plurality of coils 25 are arranged in the X direction at predetermined intervals. The plurality of coils 25 are arranged in the same direction. The coil 25 is fixed to the core 24, for example, by adhesive. By placing the adjacent coils 25 closer to each other, the effect of canceling out the magnetic flux can be enhanced. That is, the effective inductance reduction effect can be improved.

The coil 25 is formed by bending a metal plate having a predetermined thickness. The coil 25 has a main body 251 and terminal portions 252 and 253. The main body 251 is a portion wound around the central core 241. The main body 251 is a portion that overlaps with the central core 241 in the plan view. The main body 251 has first and second bottom walls 2511 and 2512, first and second side walls 2513 and 2514, and a top wall 2515.

A thickness direction of the first and second bottom walls 2511 and 2512 is approximately parallel to the Z direction. The upper surface, which is one of the plate surfaces of the first and second bottom walls 2511 and 2512, faces the lower surface of the central core 241. The exemplary first and second bottom walls 2511 and 2512 have a generally rectangular shape in plan view with the Y direction as the longitudinal direction. The upper surface of the first bottom wall 2511 faces the lower surface of the corresponding first and second central cores 2411, 2412. The upper surface of the second bottom wall 2512 faces the lower surface of the corresponding first and second central cores 2411, 2412. The first and second bottom walls 2511 and 2512 forming the same coil 25 are arranged at approximately the same position in the Z direction and are aligned in the X direction with a predetermined gap therebetween. The first and second bottom walls 2511 and 2512 face each other over the entire length in the Y direction.

The first side wall 2513 is continuous with the first bottom wall 2511. The first side wall 2513 extends in the Z direction from the first bottom wall 2511. The first side wall 2513 faces the side surface of the central core 241. The exemplary first side wall 2513 has a substantially rectangular shape when viewed in plan in the X direction. The first side wall 2513 has approximately the same length in the Y direction as the first bottom wall 2511. The first side wall 2513 is bent at an angle of approximately 90 degrees relative to the first bottom wall 2511. The thickness direction of the first side wall 2513 is approximately parallel to the X direction. The lower end of the first side wall 2513 is connected to the end of the first bottom wall 2511 opposite to the end facing the second bottom wall 2512.

Similarly, the second side wall 2514 is continuous with the second bottom wall 2512. The second side wall 2514 extends in the Z direction from the second bottom wall 2512. The second side wall 2514 faces the side surface of the central core 241 opposite to the surface that the first side wall 2513 faces. The exemplary second side wall 2514 has a substantially rectangular shape when viewed in plan in the X direction. The second side wall 2514 has approximately the same length in the Y direction as the second bottom wall 2512. The second side wall 2514 is bent at an angle of approximately 90 degrees relative to the second bottom wall 2512. The thickness direction of the second side wall 2514 is approximately parallel to the X direction. The lower end of the second side wall 2514 is connected to the end of the second bottom wall 2512 opposite to the end facing the first bottom wall 2511.

The top wall 2515 bridges the first and second side walls 2513 and 2514. The top wall 2515 extends in the X direction. One end of the top wall 2515 is continuous with the upper end of the first side wall 2513, and the other end is continuous with the upper end of the second side wall 2514. The top wall 2515 has the same length in the Y direction as the first and second side walls 2513 and 2514. In the plan view, the top wall 2515 encompasses the entire areas of the first and second side walls 2513 and 2514 and the first and second bottom walls 2511 and 2512.

The first and second bottom walls 2511 and 2512, the first and second side walls 2513 and 2514, and the top wall 2515 surround the central core 241. The first and second bottom walls 2511 and 2512, the first and second side walls 2513 and 2514, and the top wall 2515 are attached to and wound around the central core 241. The main body 251 is provided so as to overlap the gap 241G in the plan view.

The first and second terminal portions 252 and 253 are external connection terminals of the coil 25. The first and second terminal portions 252 and 253 are soldered to lands on a substrate (not shown), for example. The thickness direction of the first and second terminal portions 252 and 253 is approximately parallel to the Z direction. The first and second terminal portions 252 and 253 are connected to the main body 251.

The exemplary first and second terminal portions 252 and 253 have a generally rectangular shape in the plan view. The first terminal portion 252 is connected to the first bottom wall 2511 of the main body 251 and extends in the Y direction. The first terminal portion 252 extends in a straight line together with the first bottom wall 2511. The second terminal portion 253 is connected to the second bottom wall 2512 of the main body 251 and extends in the Y direction opposite to the first terminal portion 252. The second terminal portion 253 extends in a straight line together with the second bottom wall 2512. The first and second terminal portions 252 and 253 connected to the same main body 251 are arranged offset in the Y direction. The first and second terminal portions 252 and 253 connected to the same main body 251 are arranged offset in the X direction.

The first terminal portion 252 is provided so that at least a portion thereof overlaps the first end core 242 within the range of manufacturing variations. The second terminal portion 253 is provided so that at least a portion thereof overlaps the second end core 243 within the range of manufacturing variations. The upper surface, which is one of the plate surfaces of the first terminal portion 252, faces the lower surface of the first end core 242. The upper surface of the second terminal portion 253 faces the lower surface of the second end core 243. The first and second terminal portions 252 and 253 may overlap a portion of the central core 241 in the plan view. A portion of the exemplary first terminal portion 252 overlaps a portion of the first central core 2411. A portion of the second terminal portion 253 overlaps a portion of the second central core 2412.

The coupled inductor 22C may include a cover (not shown) in addition to the core 24 and the plurality of coils 25. The cover is placed on the top surface of the core 24 so as to cover the core 24 and the plurality of coils 25. The cover is used, for example, to prevent foreign matter from adhering to the coupled inductor 22C. The cover is used for the purpose of preventing short circuits between the coils 25 due to, for example, conductive foreign matter. The cover is used, for example, to improve the adhesiveness during transportation when the coupled inductor 22C is mounted on a substrate. The material for the cover is not particularly limited as long as the above object can be achieved. For example, it may be made of a resin or a magnetic material.

### Control Unit

The control unit (PWMCU) 30 controls the multiphase power supply 20. The control unit 30 outputs a control signal to the driver 21 to control the on/off of the driver 21. The control unit 30 performs voltage mode control by, for example, feedback of the output voltage Vout, and controls the operation of the driver 21, that is, the operation of the MOSFETs 21H and 21L. The control unit 30 determines the pulse width (duty ratio) of a PWM signal, which is a control signal, based on the output voltage Vout, and controls the output voltage Vout of the multiphase power supply 20. The control unit 30 may execute current mode control instead of voltage mode control. In FIG. 1, the PWM signal is indicated as PWM. The number added to the end of PWM indicates which phase it corresponds to.

The control unit 30 controls the plurality of drivers 21 in synchronization with each other so that the plurality of drivers 21 perform switching operations at different phases. By using a plurality of phases in this way, it is possible to increase the switching frequency artificially even if the switching frequencies of the plurality of drivers 21 are the same. This makes it possible to reduce the ripple component of the output voltage Vout and improve the responsiveness. The control unit 30 switches the driver 21 to perform the switching operation, that is, the number of drive phases, depending on the load current. The control unit 30 compares the load current with a threshold current, and increases and/or decreases the number of driving phases depending on the comparison result.

### Processor

A processor (PU) 40 is an example of a load that operates by receiving a supply of power (electric power) from the multiphase power supply 20. The processor 40 is, for example, a CPU, a GPU, or the like. The CPU is an abbreviation of a central processing unit. The GPU is an abbreviation of a graphics processing unit. The electronic control unit 10 may include only one processor 40 or multiple processors 30. The electronic control unit 10 may include multiple types of processors 40. The processor 40 may be provided as a SoC, a chiplet, or a SiP. An SoC is a single semiconductor chip on which multiple components are mounted to realize the functions of a system or device. The SoC is an abbreviation of a system on chip. The SiP is an abbreviation for System in Package.

The processor 40 executes a control program stored in a memory (not shown) to perform predetermined processing for control. The memory is a non-transitory tangible storage medium that non-temporarily stores computer-readable programs, data, and the like.

A core voltage of the processor 40 is around 1 [V] (for example, less than 1 [V]), and the load current is several tens of amperes or more (for example, 100 [A] or more). In order to accommodate such low voltages and large currents, the electronic control unit 10 includes the multiphase power supply 20 as a power supply circuit. The multiphase power supply 20 steps down the input voltage to a voltage corresponding to the core voltage of the processor 40 and outputs the voltage. By using the multiphase power supply 20, it is possible to accommodate the increased performance of the processor 40 that accompanies improvements in autonomous driving levels and the evolution of infotainment functions, and in particular to accommodate autonomous driving levels 3 and above.

In a high-performance processor 40, the current consumption fluctuates suddenly in response to the calculation processing, so many capacitors 23 are required so that a stable voltage can be supplied even when the load suddenly changes. By using the coupled inductor 22C, the effective inductance value can be reduced as described above, and therefore the responsiveness to sudden load changes is improved. This allows the capacitor 23 to be significantly reduced compared to a configuration using a normal single inductor. For example, the size of the multiphase power supply 20, and therefore the size of the electronic control unit 10, can be reduced.

### Gap and Magnetic Coupling

In the coupled inductor, as with a general coil, an inductance value is adjusted by the gap (gap) in the core formed within the coil. The gap in the core also contributes greatly to the degree of magnetic coupling between the coils.

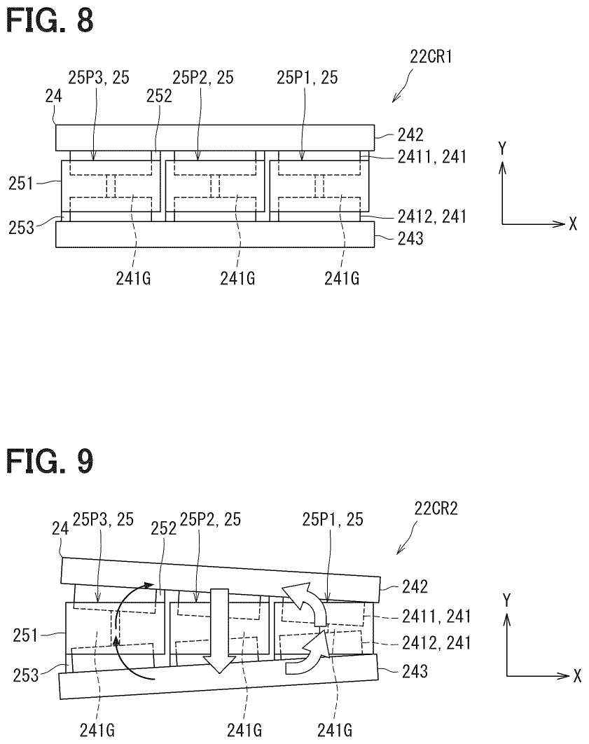

FIG. 8 is a diagram showing a reference example of a coupled inductor with a large gap. FIG. 9 is a diagram showing a reference example of a coupled inductor with different gaps due to tilted assembly. FIGS. 8 and 9 both illustrate a low coupling state. As a reference example, FIG. 8 shows a coupled inductor 22CR1, and FIG. 9 shows a coupled inductor 22CR2. The elements of the coupled inductors 22CR1 and 22CR2 are given the same reference numerals as the elements of the coupled inductor 22C described above.

In FIG. 8, the gap 241G between the first and second central cores 2411 and 2412 is uniformly large in all three central cores 241. The core material on the side of the first central core 2411 and the first end core 242 and the core material on the side of the second central core 2412 and the second end core 243 are assembled together while being spaced apart in the Y direction. Such a configuration results in weak magnetic coupling. Since all the gaps 241G are uniformly large, the magnetic coupling is uniformly weakened.

In FIG. 9, the core material on the side of the first central core 2411 and the first end core 242 and the core material on the side of the second central core 2412 and the second end core 243 are assembled in an inclined state. Such a configuration results in weak magnetic coupling. The gap 241G varies among the plurality of central cores 241, but the influence of the decrease in magnetic coupling is more pronounced in areas where the gap 241G is particularly large. In FIG. 9, the flow of magnetic flux when a current is passed through the central coil 25P2 is indicated by solid arrows. In the example shown in FIG. 9, the magnetic coupling with the coil 25P1 is strong, and the magnetic coupling with the coil 25P3 is weak.

The low degree of coupling due to the large gap 241G or tilt is caused by, for example, manufacturing variations. Furthermore, there is a risk that this may occur after the fact due to the application of external force or deterioration over time. For example, there is a risk that the gap 241G may change later due to deterioration over time of the adhesive material placed in the gap 241G. The external force is, for example, stress due to vibration or thermal stress.

### Effects of Low Degree Coupling

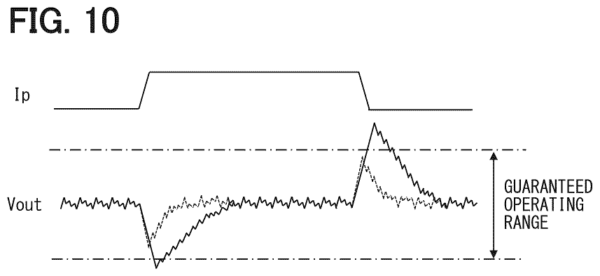

FIG. 10 is a diagram showing the Ip waveform and the Vout waveform when a coupled inductor with a low degree of magnetic coupling is used.

When a coupled inductor with a low degree of coupling is used, the effect of canceling out the magnetic flux is weakened, resulting in a high effective inductance value. As a result, the power supply response deteriorates when the current consumption Ip of a load such as a processor suddenly changes. As shown in FIG. 10, the fluctuation of the output voltage Vout due to the sudden change in the consumption current Ip becomes large, and exceeds the guaranteed operating range of the load. In particular, when the consumption current Ip decreases suddenly, the amount of energy stored in the inductor directly leads to an overshoot of the power supply voltage, which has a large effect.

Furthermore, in the coupled inductors, magnetic fluxes cancel each other out, preventing magnetic saturation. However, if the degree of coupling is low, the effect of canceling out the magnetic flux weakens, leading to magnetic saturation. A magnetically saturated coil has a significantly reduced inductance value, which may prevent normal switching operation.

### Magnetic Coupling Degree Detection Device

FIG. 1 shows an example of a magnetic coupling degree detection device. The magnetic coupling degree detection device 50 includes a current detector (CD) 51 and a coupling degree detector (MCD) 52.

The current detector 51 detects the current flowing through the driver 21. The means for detecting the current is not particularly limited. The exemplary current detector 51 is provided integrally with the driver 21. The current detector 51 may be a current sensor provided on the same semiconductor chip as the MOSFETs 21H and 21L that form the driver 21, for example. Alternatively, the current detector 51 may be provided separately from the driver 21.

The current detector 51 detects the current flowing through the driver 21 of the corresponding phase, and outputs a current detection signal (CDS) to the coupling degree detector 52. The magnetic coupling degree detection device 50 includes at least one current detector 51. The current detector 51 is provided at least in the phase required to detect the degree of magnetic coupling.

The coupling degree detector 52 detects the degree of magnetic coupling of the coupled inductor 22C based on the current value detected by the current detector 51. The coupling degree detector 52 detects the degree of magnetic coupling between the inductors 22, that is, between the coils 25, based on the current flowing through the driver 21 of at least one phase. The exemplary coupling degree detector 52 is provided separately from the driver 21, the control unit 30, and the processor 40 that constitute the multiphase power supply 20. The coupling degree detector 52 is implemented as a discrete component.

The exemplary coupling degree detector 52 detects the magnetic coupling degree of all combinations of an inductor in any one of the multiple phases and an inductor in any other phase excluding the any one of the multiple phases, based on the current value of the driver 21 in the any one of the multiple phases. The coupling degree detector 52 shown in FIG. 1 detects the degree of magnetic coupling between the inductor 22 of Phase 1 and the inductor 22 of Phase 2, and the degree of magnetic coupling between the inductor 22 of Phase 1 and the inductor 22 of Phase 3, based on the current value of the driver (DR1) 21 of Phase 1. That is, the coupling degree detector 52 detects the degree of magnetic coupling between the coils 25P1 and 25P2 and the degree of magnetic coupling between the coils 25P1 and 25P3.

Alternatively, the coupling degree detector 52 may detect the degree of magnetic coupling of the coils 25P2 and 25P3 and the degree of magnetic coupling of the coils 25P2 and 25P1 based on the current value of the driver (DR2) 21 of Phase 2. The coupling degree detector 52 may detect the degree of magnetic coupling between the coils 25P3 and 25P1 and the degree of magnetic coupling between the coils 25P3 and 25P2 based on the current value of the driver (DR3) 21 of Phase 3. The coupling degree detector 52 may detect the degree of magnetic coupling for the currents of a plurality of drivers 21, for example, for the currents of all drivers 21.

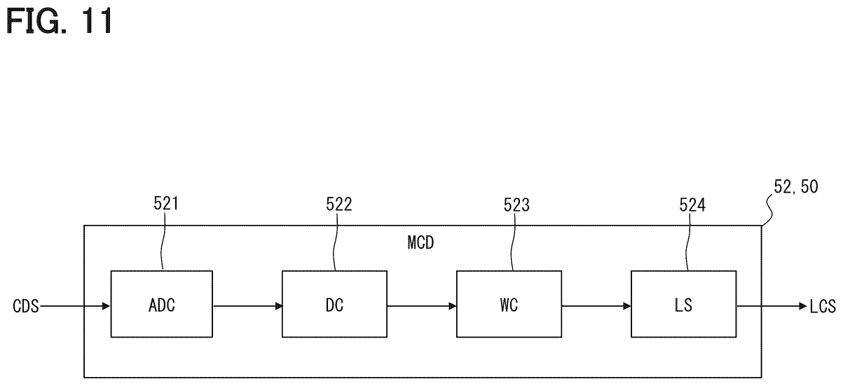

FIG. 11 is a block diagram illustrating an example of a coupling degree detector. At least a part of the functions of the coupling degree detector 52 may be realized by hardware, or at least a part of the functions may be realized by software. The coupling degree detector 52 may be configured to include, for example, an analog circuit or a digital circuit. The exemplary coupling degree detector 52 includes an A/D converter (ADC) 521, a differential calculator (DC) 522, a window comparator (WC) 523, and a latch unit (LS) 524.

The A/D converter 521 acquires the current value detected by the current detector 51, that is, the current detection signal (CDS), and converts it into a digital signal. The A/D converter 521 converts the current value into a digital signal and outputs the converted signal to the differential calculator 522. The differential calculator 522 performs a differential calculation on the output of the A/D converter 521, that is, the current value. The differential calculator 522 outputs the calculation result to the window comparator 523. The coupling degree detector 52 differentiates the current of the driver 21, which is captured as a digital value by the A/D converter 521, and calculates the gradient of the current flowing through the coupled inductor 22C.

The window comparator 523 determines whether the input signal is within a predetermined range, and outputs the determination result to the latch unit 524. The window comparator 523 compares the differential value of the input signal, that is, the gradient of the current, with an upper threshold and a lower threshold. The window comparator 523 outputs a High signal when the differential value is within a predetermined range, that is, between the upper threshold and the lower threshold. The window comparator 523 outputs a Low signal when the differential value is less than the lower threshold or exceeds the upper threshold.

When the degree of magnetic coupling of the coupled inductor 22C is low, the current gradient, which is the differential value, becomes small. The window comparator 523 compares the current gradient with the upper threshold to determine whether the gradient is smaller than a desired gradient, that is, whether the degree of magnetic coupling is low. Furthermore, during the period when all the drivers 21 are turned off, the current flowing through the drivers 21 decreases, and the current gradient becomes negative. The window comparator 523 compares the current gradient with the lower threshold to determine whether or not it is a period in which all of the drivers 21 are turned off. That is, the window comparator 523 compares the current gradient with the lower threshold to exclude the periods when all of the drivers 21 are turned off. When the current gradient is within a predetermined range, the window comparator 523 determines that the degree of magnetic coupling is lower than when it exceeds the upper threshold, and outputs a High signal.

The upper threshold, which is the upper limit of the predetermined range, is preferably set in accordance with the current gradient corresponding to the degree of magnetic coupling of coupled inductor 22C so that the guaranteed operating voltage of processor 40 is not exceeded when the load on processor 40 fluctuates. In other words, the upper threshold is preferably set in accordance with the current gradient corresponding to the allowable degree of magnetic coupling so as not to exceed the guaranteed operating voltage of the processor 40 when the load on the processor 40 fluctuates.

The lower threshold, which is the lower limit of the predetermined range, is preferably set in accordance with the current gradient corresponding to the degree of magnetic coupling when gap 241G is at its maximum manufacturing value, that is, the maximum manufacturing tolerance. When the degree of magnetic coupling is very small, it is conceivable that the current gradient will not be positive even during the period when the driver 21 is turned on. The lower threshold may be, for example, a value less than zero.

The latch unit 524 takes in the logical value of the input signal at a specific timing and holds that state as an output. The latch unit 524 is, for example, an RS latch. When the reset signal is at a low level and the input signal from the window comparator 523 is at a high level, the latch unit 524 outputs a high-level signal. When the reset signal is at a low level and the input signal from the window comparator 523 is at a low level, the latch unit 524 holds the previous state. When the reset signal is at a high level and the input signal from the window comparator 523 is at a low level, the latch unit 524 outputs a low-level signal.

The output of the latch unit 524 is input to the processor 40 as a low coupling degree notification signal (LCS). The period during which the latch unit 524 outputs a high-level signal corresponds to the period during which the low coupling degree notification is turned on. The period during which the latch unit 524 outputs a low-level signal corresponds to the period during which the low coupling degree notification is turned off. For example, when the reset signal is at a low level and the input signal from the window comparator 523 goes to a high level, the latch unit 524 turns on the low coupling degree notification and outputs a high-level signal.

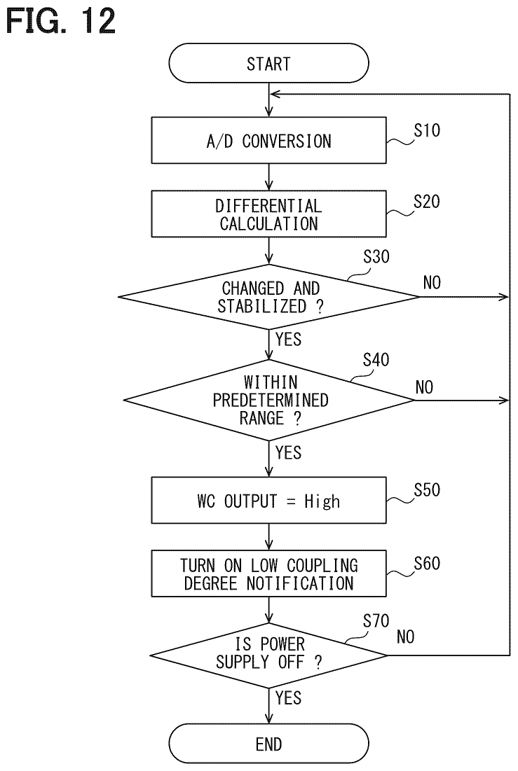

FIG. 12 is a flowchart showing an example of a process executed by the coupling degree detector, ie, a coupling degree detection process. For example, when power is supplied and the coupling degree detector 52 is started up, the coupling degree detector 52 executes a coupling degree detection process.

The coupling degree detector 52 performs A/D conversion of the current detection signal (step S10). The coupling degree detector 52 receives the current detection signal from the current detector 51 and performs A/D conversion.

Next, the coupling degree detector 52 performs a differential calculation of the current value (step S20). The coupling degree detector 52 differentiates the A/D converted current value. The differential value obtained by the calculation corresponds to the gradient of the current.

As shown in the timing chart described later, the differential value changes at the timing when the PWM signal switches between on and off. For example, the differential value changes at the timing when any of the PWM signals is turned on.

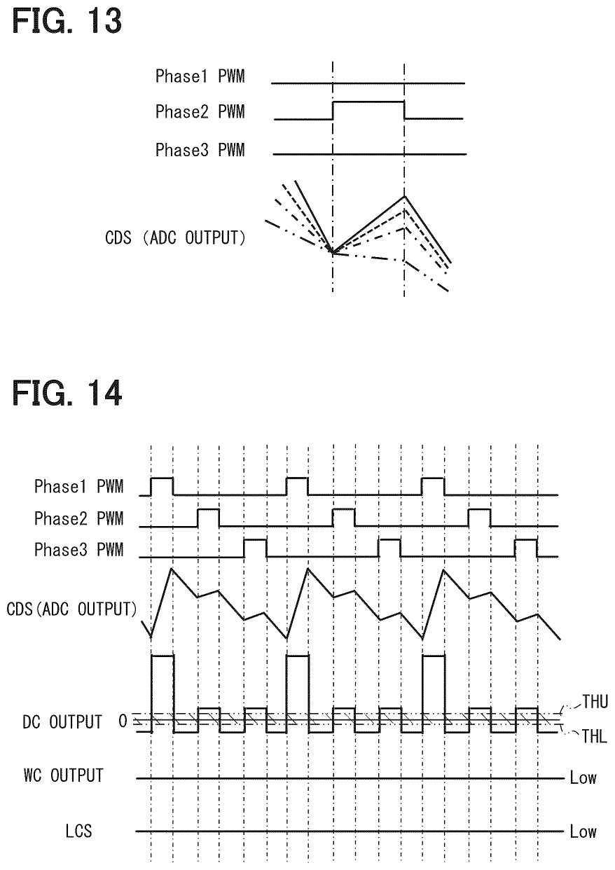

FIG. 13 is a diagram showing the relationship between the strength of magnetic coupling and the current gradient. FIG. 13 shows the current gradient when the PWM signal of Phase 2 switches from off to on. The solid line showing the current gradient indicates a state in which the magnetic coupling is strong. The dashed line showing the current gradient indicates the normal state of magnetic coupling. The dashed line indicating the current gradient indicates a state in which the magnetic coupling is weak. The dashed two-dot line showing the current gradient indicates a state in which the magnetic coupling is very weak.

Normally, when any of the PWM signals is turned on, the current gradient takes a positive value. “Normal” refers to the state at the center of the manufacturing tolerance. When the magnetic coupling is stronger than normal, the current gradient takes a positive value with a larger gradient than normal. When the magnetic coupling is weaker than normal, the current gradient takes a positive value with a smaller gradient than normal. However, when the magnetic coupling is very weak, the current gradient may take a negative value even when the PWM signal is on. In the present example, the degree of magnetic coupling is determined when the current gradient changes and the changed current gradient becomes stable.

After executing step S20, the coupling degree detector 52 determines whether the current gradient has changed and stabilized at a constant value (step S30). This makes it possible to suppress erroneous detection that occurs when the current gradient passes through a predetermined range in the process of changing. When the current gradient of the current value has not changed from the previous value, or when the current gradient is changing and not stable, the coupling degree detector 52 returns to step S10 and executes the processes from step S10 onwards again. When the current gradient changes and then stabilizes at a constant value, the coupling degree detector 52 then determines whether the current gradient is within a predetermined range (step S40). The predetermined range is the range from the lower threshold to the upper threshold set in the window comparator 523. When the current gradient is outside the predetermined range, the coupling degree detector 52 returns to step S10 and executes the processes from step S10 onwards again.

When the current gradient is within the predetermined range, the window comparator 523 of the coupling degree detector 52 then outputs a high-level signal (step S50). Next, the coupling degree detector 52 turns on the low coupling degree notification (step S60). The coupling degree detector 52 outputs a high-level signal to the processor 40.

Next, the coupling degree detector 52 determines whether the power supply to the coupling degree detector 52 is off (step S70). When the power supply is off, the coupling degree detection process ends. When the power supply is not off, the coupling degree detector 52 returns to step S10 and executes the processes from step S10 onwards again.

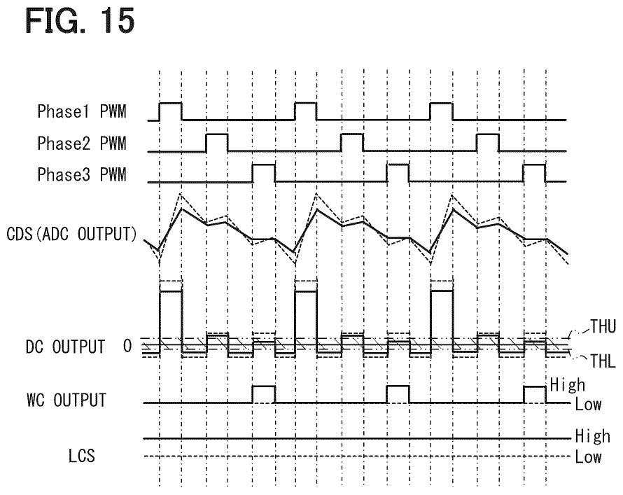

FIG. 14 is a timing chart showing an example of various signal waveforms when the assembly is performed normally. FIG. 15 is a timing chart showing an example of various signal waveforms when the assembly is tilted. FIGS. 14 and 15 show, in each phase, the PWM waveforms, the output of the A/D converter (ADC) 521 of the current detection signal (CDS), the output of the differential calculator (DC) 522, the output of the window comparator (WC) 523, and the low coupling degree notification signal (LCS). In FIGS. 14 and 15, the ON period of a predetermined duty ratio is shown in a simplified manner. THU indicates the upper threshold of the window comparator 523, and THL indicates the lower threshold of the window comparator 523.

FIG. 14 shows the waveform in a state where the gaps 241G are approximately equal to each other and the gaps 241G are approximately aligned with the center of the manufacturing tolerances, similar to the configuration shown in FIG. 4. As described above, since the current of the driver (DR1) 21 is used, the current flowing through the driver 21 increases rapidly with a positive slope at the ON timing of the PWM signal of Phase 1. As a result, the output of the differential calculator 522 switches from negative to positive and exceeds the upper threshold THU.

By using the coupled inductor 22C, the inductors 22 of each phase are magnetically coupled to each other, so that the current flowing through the driver 21 increases with a positive slope even when the PWM signals of Phases 2 and 3 are turned on. Although the gradient of the current due to magnetic coupling is smaller than the gradient of the current at the on timing of the PWM signal of Phase 1, the output of the differential calculator 522 exceeds the upper threshold THU.

When the PWM signal is switched from on to off, the current flowing through the driver 21 decreases, and the output of the differential calculator 522 indicates a negative value. During the period when all the PWM signals of Phases 1, 2, and 3 are off, the output of the differential calculator 522 is below the lower threshold THL.

Therefore, the output of the differential calculator 522 does not fall within the predetermined range defined by the upper threshold THU and the lower threshold THL. The coupling degree detector 52 outputs a low-level signal as a coupling degree detection signal. In other words, the low coupling degree notification is maintained in the OFF state.

FIG. 15 shows the waveforms in a state where the core material on the side of the first central core 2411 and the first end core 242 and the core material on the side of the second central core 2412 and the second end core 243 are assembled in an inclined state, similar to the configuration shown in FIG. 9. Specifically, the waveform is shown when using the coupled inductor 22C in which the gap 241G on the coil 25P1 side is narrow and the gap 241G on the coil 25P3 side is wide. By assembling it in the inclined state, the output of the differential calculator 522 is within a predetermined range defined by the upper threshold THU and the lower threshold THL at the ON timing of the PWM signal of Phase 3.

Therefore, at the ON timing of the PWM signal of Phase 3, the output of the window comparator 523 becomes a high level. After the output of the window comparator 523 becomes high level for the first time, the coupling degree detector 52 outputs a high-level signal as the coupling degree detection signal. In other words, the low coupling degree notification is maintained in the ON state. FIG. 15 shows the waveform after the low coupling degree notification has already been switched from the OFF state to the ON state.

### Overview of First Embodiment

The magnetic coupling degree detection device 50 of the present embodiment includes the current detector 51 and the coupling degree detector 52. The current detector 51 detects the current flowing through the driver 21 of the multiphase power supply 20 that includes the coupled inductor 22C. The coupling degree detector 52 detects the degree of magnetic coupling of the coupled inductor 22C based on the current value detected by the current detector 51. The coupling degree detector 52 determines that the degree of magnetic coupling is low when the differential value of the current value is within a predetermined range, compared to when the differential value of the current value exceeds the upper limit of the predetermined range. In the exemplary magnetic degree coupling degree detector 50, the upper threshold THU of the window comparator 523 corresponds to the upper limit of the predetermined range. The range defined by the upper threshold THU and the lower threshold THL corresponds to the predetermined range.

The magnetic coupling degree detection device 50 detects the degree of magnetic coupling between the inductors 22 in the coupled inductor 22C, that is, between the coils 25, based on the current flowing through the driver 21. The gradient of the current, that is, the differential value, becomes larger as the magnetic coupling increases, and becomes smaller as the magnetic coupling decreases. Furthermore, in the period when the driver 21 of any phase is off, the current decreases and the differential value becomes negative. The coupling degree detector 52 determines that the degree of magnetic coupling is low, that is, the degree of magnetic coupling is low, when the differential value of the current value is within the predetermined range. Therefore, it is possible to detect a low degree of coupling of the coupled inductor 22C. For example, it is possible to detect low coupling degree due to manufacturing variations, deterioration over time, etc.

As shown in the example, in a configuration in which the multiphase power supply 20 supplies power to the processor 40, which is a load, the upper limit of the predetermined range may be set to match the current gradient corresponding to the degree of magnetic coupling of the coupled inductor 22C so that the guaranteed operating voltage of the processor 40 is not exceeded when the load on the processor 40 fluctuates. This makes it possible to determine whether the degree of coupling is low within a range that has a real effect. When the differential value is equal to or less than the upper limit, it can be determined that the degree of coupling is low and may exceed the guaranteed operating voltage.

As illustrated, the central core 241 of the core 24 of the coupled inductor 22C may be divided into a plurality of parts in a direction perpendicular to the direction in which the coils 25 are arranged, to have gaps 241G. In such a configuration, the lower limit of the predetermined range may be set in accordance with the current gradient corresponding to the degree of magnetic coupling when gap 241G is at the maximum value in manufacturing. According to this configuration, the lower limit is set according to the maximum value allowable in terms of manufacturing tolerance, so that it is possible to determine the low degree of coupling within the range that can occur in manufacturing.

As shown in the example, the coupling degree detector 52 may detect the magnetic coupling degree of all combinations of the inductor 22 of any one phase and the inductors 22 of the other phases excluding the any one phase, based on the current value of the driver 21 of any one phase among the multiple phases. That is, the coupling degree detector 52 may detect the degree of magnetic coupling based on only the current flowing through one of the plurality of drivers 21. This allows the magnetic coupling degree detection device 50 to be simplified compared to a configuration in which the magnetic coupling is detected for the current value of each phase. For example, it is possible to reduce costs.

The electronic control unit 10 of the present embodiment includes the multiphase power supply 20, the control unit 30, the processor 40, and the magnetic coupling degree detection device 50. The multiphase power supply 20 has a plurality of phases each including the driver 21 and the inductor 22, and the inductor 22 of each phase is configured by a coupled inductor 22C. The control unit 30 controls the on/off of the driver 21. The processor 40 operates by receiving power from the multiphase power supply 20. The magnetic coupling degree detection device 50 includes the current detector 51 that detects the current flowing through the driver, and the coupling degree detector 52 that detects the magnetic coupling of the coupled inductor 22C based on the current value detected by the current detector 51. The coupling degree detector 52 determines that the degree of magnetic coupling is low when the differential value of the current value is within a predetermined range, compared to when the differential value of the current value exceeds the upper limit of the predetermined range. Therefore, similar to the magnetic coupling degree detection device 50 described above, it is possible to detect a low degree of coupling of the coupled inductor 22C. For example, it is possible to detect low coupling degree due to manufacturing variations, deterioration over time, etc.

### Second Embodiment

A second embodiment is a modification of the preceding embodiment as a basic configuration and may incorporate description of the precedent embodiments. In the previous embodiment, the differential value itself was used. Alternatively, the average value of the differential values may be used as the differential value.

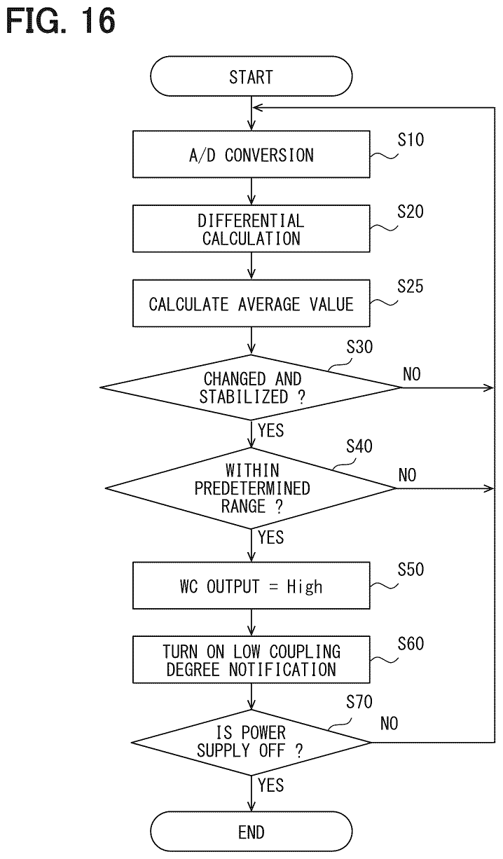

FIG. 16 is a flowchart showing an example of process executed by the coupling degree detector in the magnetic coupling degree detection device and electronic control unit according to the present embodiment. FIG. 16 corresponds to FIG. 12. The configuration of the coupling degree detector 52 is the same as that of the preceding embodiment. As shown in FIG. 16, the processes of steps S10, S20, S30, S40, S50, S60, and S70 are the same as those in the preceding embodiment.

After executing the process of step S20, the coupling degree detector 52 then calculates the average value of the differential values (step S25). The average value is the average value of the differential values over a predetermined period. The predetermined period is a period shorter than one switching cycle. The predetermined period may be, for example, a period shorter than the ON period of the corresponding phase. The coupling degree detector 52 executes a determination process using the average value in steps S30 and S40.

The differential calculator 522 may calculate the average value of the differential values and output the average value. The window comparator 523 may calculate the average value of the differential values. An average value calculator may be provided between the differential calculator 522 and the window comparator 523 to hold the output of the differential calculator 522 for a predetermined period and calculate an average value. The other configurations are the same as those described in the previous embodiment.

### Overview of second embodiment

As illustrated, the coupling degree detector 52 may detect the degree of magnetic coupling by using, as the differential value, an average value of the differential value over a predetermined period shorter than one switching period. This makes it possible to prevent the differential value from momentarily falling into a predetermined range due to noise, resulting in erroneous determination. That is, the detection accuracy of low coupling degree can be improved.

### Third Embodiment

A second embodiment is a modification of the preceding embodiment as a basic configuration and may incorporate description of the precedent embodiments. In the preceding embodiment, the coupling degree detector is provided separately from the other elements that configure the electronic control unit. Alternatively, the coupling degree detector may be provided integrally with other elements that constitute the electronic control unit.

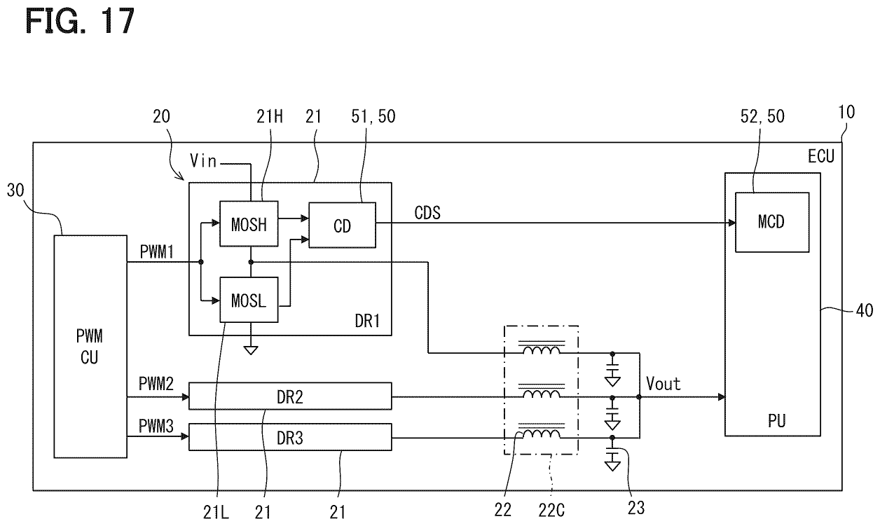

FIG. 17 is a diagram illustrating an example of an electronic control unit according to the present embodiment. FIG. 17 corresponds to FIG. 1. In the electronic control unit 10, the coupling degree detector 52 is provided in the processor 40. The coupling degree detector 52 is provided integrally with the processor 40. In the illustrated electronic control unit 10, one coupling degree detector 52 that detects the magnetic coupling degree based on the current flowing through the driver (DR1) 21 of Phase 1 is provided in the processor 40. The other configurations are the same as those described in the previous embodiment.

### Overview of Third Embodiment

As illustrated, the coupling degree detector 52 may be provided in the processor 40. By providing the coupling degree detector 52 within the processor 40, the electronic control unit 10 can be simplified compared to when the coupling degree detector 52 is configured as a discrete unit. For example, the coupling degree detector 52 can be configured inexpensively.

### Modification Example

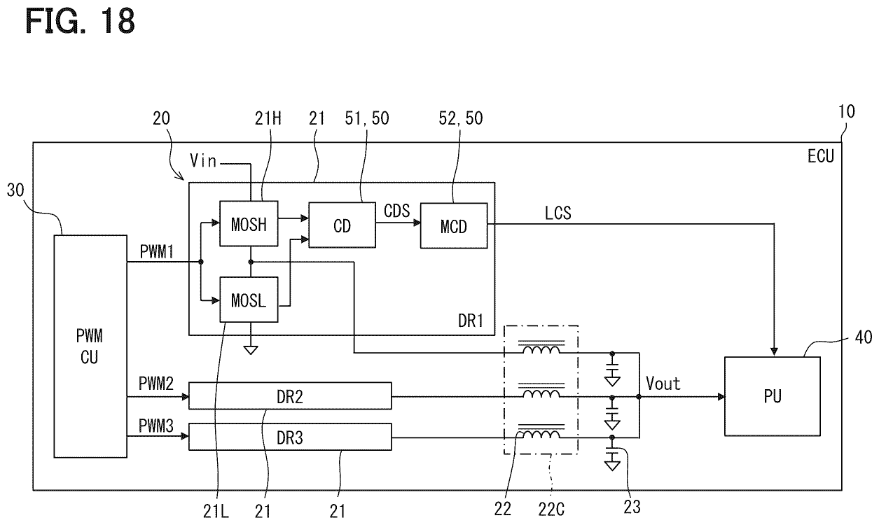

As shown in FIG. 18, the coupling degree detector 52 may be provided in the driver 21. By providing the coupling degree detector 52 in the driver 21 of the corresponding phase, the electronic control unit 10 can be simplified compared to when the coupling degree detector 52 is configured as a discrete unit. For example, the coupling degree detector 52 can be configured inexpensively.

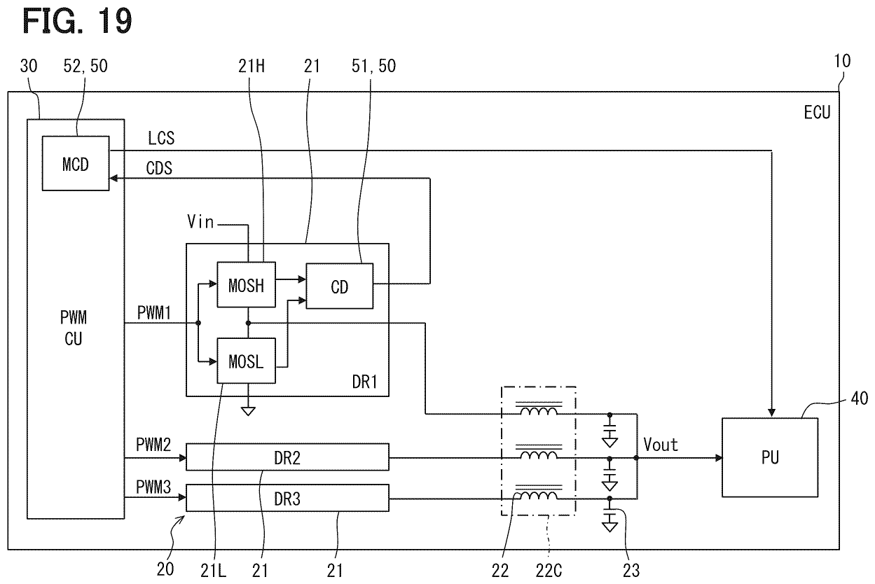

As shown in FIG. 19, the coupling degree detector 52 may be provided in the control unit 30. By providing the coupling degree detector 52 integrally with the control unit 30, the electronic control unit 10 can be simplified compared to when the coupling degree detector 52 is configured as a discrete unit. For example, the coupling degree detector 52 can be configured inexpensively.

The configuration shown in the present embodiment can be combined with either the configuration described in the first embodiment or the configuration described in the second embodiment.

### Fourth Embodiment

A second embodiment is a modification of the preceding embodiment as a basic configuration and may incorporate description of the precedent embodiments. In the previous embodiment, when the low coupling degree is detected, a low coupling degree notification is turned on. In addition, the low coupling degree notification may trigger the processor to execute a predetermined process.

As described above, when the degree of magnetic coupling of the coupled inductor 22C is low, the effective inductance value becomes high, and the power supply response deteriorates when the current consumption Ip of the processor 40 suddenly changes. The sudden change in the current consumption Ip causes the output voltage Vout to fluctuate greatly, exceeding the guaranteed operating range of the processor 40. For example, when switching from automatic driving mode to manual driving mode, when the consumption current Ip suddenly decreases, the amount of energy stored in the inductor directly leads to an overshoot of the power supply voltage, which has a large impact. There is a risk that the processor 40 may malfunction.

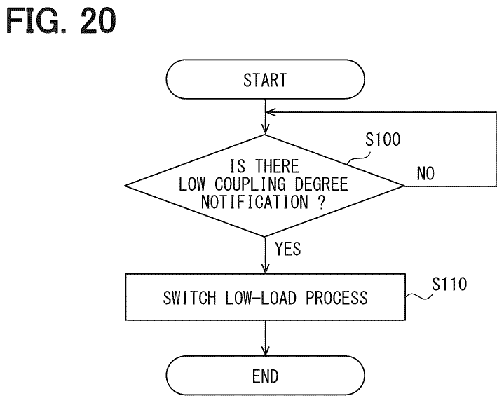

FIG. 20 is a diagram showing an example of process executed by the processor in the electronic control unit according to the present embodiment. For example, when power is supplied and the processor 40 of the electronic control unit 10 is started, the processor 40 executes the process shown in FIG. 20.

The processor 40 determines whether or not there is a low coupling degree notification from the magnetic coupling degree detection device 50 (step S100). The processor 40 determines whether or not a low-level signal indicating a low coupling degree has been received as the low coupling degree notification signal (LCS). When there is no low coupling degree notification, the process of step S100 is repeated.

When there is a low coupling degree notification, the processor 40 switches to low-load process (step S110) and ends the series of processes. When high-load process is being executed, the processor 40 switches the process to low-load process in step S110. When the low-load process is being executed, the processor 40 maintains the low-load process by the process in step S110. The processor 40 maintains the low-load process until, for example, the low coupling degree notification is released. The other configurations are the same as those described in the previous embodiment.

### Overview of Fourth Embodiment

As illustrated, when the coupling degree detector 52 determines that the magnetic coupling degree is low, it may notify the processor 40 of the decrease in magnetic coupling degree. When the processor 40 receives the low coupling degree notification, the processor 40 may reduce the processing load compared to before receiving the low coupling degree notification. Even if the load fluctuation characteristics of the multiphase power supply 20 deteriorate due to a decrease in the magnetic coupling degree, the output voltage Vout can be prevented from exceeding the guaranteed operating range of the processor 40.

The configuration shown in the present embodiment can be combined with any of the configurations described in the first embodiment, the second embodiment, and the third embodiment.

### Other Embodiments

The disclosure in this specification and drawings is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may have additional portions that may be added to the embodiments. The disclosure encompasses omission of components and/or elements of the embodiments. The disclosure encompasses the replacement or combination of components and/or elements between one embodiment and another. The disclosed technical scope is not limited to the description of the embodiments. Some aspects of the disclosed technical scope are indicated by the recitations of the claims, and should further be construed to include all modifications within the meaning and scope equivalent to those recitations.

The disclosure in the specification, drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

When an element or a layer is described as “disposed above” or “connected”, the element or the layer may be directly disposed above or connected to another element or another layer, or an intervening element or an intervening layer may be present therebetween. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. The description of A and/or B means at least one of A and B.

Spatial relative terms “inside”, “outside”, “back”, “bottom”, “low”, “top”, “high”, etc. are used herein to facilitate the description that describes relationships between one element or feature and another element or feature. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in the other direction (rotated 90 degrees or in any other direction) and the spatially relative terms used herein are interpreted accordingly.

What is claimed is:

1. A magnetic coupling degree detection device, comprising:
a processor with a memory storing computer program code executable by the processor, the processor configured to cause the detection device to:
detect a current flowing in a driver of a multiphase power supply in which inductors of a plurality of phases are configured by a coupled inductor and which supplies power to a load;
detect a magnetic coupling degree of the coupled inductor based on a current value; and
determine that the magnetic coupling degree is low when a differential value of the current value is within a predetermined range, compared to when the differential value exceeds an upper limit of the predetermined range.

2. The magnetic coupling degree detection device according to claim 1, wherein
the load includes the processor, and
the upper limit of the predetermined range is set in accordance with a current gradient corresponding to the magnetic coupling degree of the coupled inductor such that a guaranteed operating voltage of the processor is not exceeded when the load on the processor fluctuates.

3. The magnetic coupling degree detection device according to claim 1, wherein
the coupled inductor has a core and a plurality of coils that are arranged in the core, aligned in a predetermined direction, and magnetically coupled to each other,
the coil has a main body wound around a terminal portion connected to the main body,
the core has a plurality of central cores provided individually for the coils and around which the main bodies of the corresponding coils are wound, a first end core to which one ends of the plurality of central cores are connected, and a second end core to which the other ends of the plurality of central cores are connected, and which is arranged so as to sandwich the plurality of central cores between the first end core and the second end core in an orthogonal direction perpendicular to the predetermined direction,
the core portion is divided into a plurality of portions in the orthogonal direction to have gaps, and
a lower limit of the predetermined range is set in accordance with a current gradient corresponding to the magnetic coupling degree when the gap is at a maximum value in manufacturing.

4. The magnetic coupling degree detection device according to claim 1, wherein
the processor is further configured to cause the detection device to detect the magnetic coupling degree of all combinations of an inductor of any one of the plurality of phases and an inductor of any other phase excluding the any one of the plurality of phases, based on a current value of the driver of the any one of the plurality of phases.

5. The magnetic coupling degree detection device according to claim 1, wherein
the processor is further configured to cause the detection device to detect the magnetic coupling degree by using, as the differential value, an average value of the differential value over a predetermined period shorter than one switching period of the driver.

6. A magnetic coupling degree detection device, comprising:
a current detector configured to detect a current flowing in a driver of a multiphase power supply in which inductors of a plurality of phases are configured by a coupled inductor and which supplies power to a load; and
a coupling degree detector configured to detect a magnetic coupling degree of the coupled inductor based on a current value detected by the current detector, wherein
the coupling degree detector determines that the magnetic coupling degree is low when a differential value of the current value is within a predetermined range, compared to when the differential value exceeds an upper limit of the predetermined range.

7. The magnetic coupling degree detection device according to claim 6, wherein
the load includes a processor, and
the upper limit of the predetermined range is set in accordance with a current gradient corresponding to the magnetic coupling degree of the coupled inductor such that a guaranteed operating voltage of the processor is not exceeded when the load on the processor fluctuates.

8. The magnetic coupling degree detection device according to claim 6, wherein
the coupled inductor has a core and a plurality of coils that are arranged in the core, aligned in a predetermined direction, and magnetically coupled to each other,
the coil has a main body wound around a terminal portion connected to the main body,
the core has a plurality of central cores provided individually for the coils and around which the main bodies of the corresponding coils are wound, a first end core to which one ends of the plurality of central cores are connected, and a second end core to which the other ends of the plurality of central cores are connected, and which is arranged so as to sandwich the plurality of central cores between the first end and the second end in an orthogonal direction perpendicular to the predetermined direction,
the core portion is divided into a plurality of portions in the orthogonal direction to have gaps, and
a lower limit of the predetermined range is set in accordance with a current gradient corresponding to the magnetic coupling degree when the gap is at a maximum value in manufacturing.

9. The magnetic coupling degree detection device according to claim 6, wherein
the coupling degree detector detects the magnetic coupling degree of all combinations of an inductor of any one of the plurality of phases and an inductor of any other phase excluding the any one of the plurality of phases, based on a current value of the driver of the any one of the plurality of phases.

10. The magnetic coupling degree detection device according to claim 6, wherein
the coupling degree detector detects the magnetic coupling degree by using, as the differential value, an average value of the differential value over a predetermined period shorter than one switching period of the driver.

11. An electric control unit, comprising:
a multiphase power supply having a plurality of phases each including a driver and an inductor, the inductor of each phase being configured by a coupled inductor;
a control unit configured to control an on/off of the driver;
a processor configured to receive power from the multiphase power supply and operate; and
a magnetic coupling degree detection device including a current detector configured to detect a current flowing in the driver, and a coupling degree detector configured to detect a magnetic coupling degree of the coupled inductor based on a current value detected by the current detector, wherein
the coupling degree detector determines that the magnetic coupling degree is low when a differential value of the current value is within a predetermined range, compared to when the differential value exceeds an upper limit of the predetermined range.

12. The electric control unit according to claim 11, wherein
the coupling degree detector is provided in the processor.

13. The electric control unit according to claim 11, wherein
the coupling degree detector is provided in the driver.

14. The electric control unit according to claim 11, wherein
the coupling degree detector is provided in the control unit.

15. The electric control unit according to claim 11, wherein,
when the coupling degree detector determines that the magnetic coupling degree is low, the coupling degree detector notifies the processor of a decrease in magnetic coupling degree, and
upon receiving a notification, the processor reduces a processing load compared to before receiving the notification.
